(19) United States
(12) Patent Application Publication
(10) Pub. No.: US 2026/0266879 A1
(43) Pub. Date: Sep. 10, 2026

(54) POWER DEVICE AND A METHOD FOR DETERMINING WHETHER A LOAD IS PRESENT

(71) Applicant: CYBER POWER SYSTEMS, INC., TAIPEI CITY (TW)

(72) Inventors: WEN-PIN LAI, TAIPEI CITY (TW); YUNG-HAO PENG, TAIPEI CITY (TW); LI-ANG CHANG, TAIPEI CITY (TW)

(21) Appl. No.: 19/215,531

(22) Filed: May 22, 2025

(30) Foreign Application Priority Data
Mar. 6, 2025 (CN) 2025102606419

(51) Int. Cl. G01R 21/00; G01R 21/06; H02J 7/00

(52) U.S. Cl. CPC G01R 21/006; G01R 21/005; G01R 21/06; H02J 7/80

(57) ABSTRACT

A power device and a method for determining whether a load is present are provided. The power device comprises an AC output terminal, a voltage sensor, a current sensor, and a control unit. The control unit is used to obtain, respectively through the voltage sensor and the current sensor, n instantaneous voltage values and n instantaneous current values from the AC output terminal during a first time period, calculate a voltage RMS value, a current RMS value, an apparent power value, and a real power value based on these values, and calculate a power factor value based on the apparent power value and the real power value. The control unit is further used to determine whether the power factor value is greater than a first threshold value. If the determination result is positive, the control unit determines that a load is electrically coupled to the AC output terminal.

### BACKGROUND OF THE INVENTION

### Field of the Invention

The present invention relates to the field of power supply technology, and more particularly to a power device and a method for determining whether a load is present.

### Description of Related Art

A power device, such as an uninterruptible power system (UPS), a power distribution unit (PDU), or an automatic transfer switch (ATS), is used to supply power to at least one load, and to monitor and manage the power supply to the loads.

In order to monitor and manage power supply, current power devices all have the function of measuring load voltage and load current, so as to provide voltage readings and current readings to users for review at any time. However, under no-load conditions, load current measurement is often affected by noise and level drift, resulting in abnormal current readings in power devices. This is explained with reference to FIGS. 1 to 3.

FIG. 1 shows an ideal voltage waveform 102 and an ideal current waveform 104 at an AC output terminal of a power device under no-load conditions. It can be seen from the ideal current waveform 104 that the current reading generated by the power device is zero. FIG. 2 shows a voltage waveform 202 and a current waveform 204 obtained by measuring the AC output terminal of the power device under no-load conditions. It can be seen from the current waveform 204 that the current measurement is affected by the level drift, resulting in the current reading generated by the power device not being zero. FIG. 3 also shows a voltage waveform 302 and a current waveform 304 obtained by measuring the AC output terminal of the power device under no-load conditions. It can be seen from the current waveform 304 that the current measurement is affected by noise, resulting in the current reading generated by the power device not being zero.

It can be seen from this that when the power device is under no-load conditions, if it generates an abnormal current reading, the user may mistakenly believe that a load is electrically coupled to the power device (i.e., the user may mistakenly believe that a load is present), which may cause management problems.

### SUMMARY OF THE INVENTION

An object of the present invention is to provide a power device that can determine whether a load is present.

Another object of the present invention is to provide a method for determining whether a load is present.

To achieve the above object, the present invention provides a power device, which comprises an AC output terminal, a voltage sensor, a current sensor and a control unit. The voltage sensor is electrically coupled to the AC output terminal, the current sensor is connected in series with the AC output terminal, and the control unit is electrically coupled to the voltage sensor and the current sensor. The control unit is used to obtain, respectively through the voltage sensor and the current sensor, n instantaneous voltage values and n instantaneous current values from the AC output terminal during a first time period, wherein n is a natural number. The control unit is also used to calculate a voltage RMS value based on the n instantaneous voltage values, to calculate a current RMS value based on the n instantaneous current values, to calculate an apparent power value based on the voltage RMS value and the current RMS value, to calculate a real power value based on the n instantaneous voltage values and the n instantaneous current values, and to calculate a power factor value based on the apparent power value and the real power value. The control unit is further used to determine whether the power factor value is greater than a first threshold value to obtain a first determination result, and to determine that a load is electrically coupled to the AC output terminal when the first determination result is yes.

To achieve the above-mentioned another object, the present invention provides a method for determining whether a load is present, which is applicable to a power device. The method comprises the following steps: obtaining n instantaneous voltage values and n instantaneous current values from an AC output terminal of the power device during a first time period, wherein n is a natural number; calculating a voltage RMS value based on the n instantaneous voltage values, and calculating a current RMS value based on the n instantaneous current values; calculating an apparent power value based on the voltage RMS value and the current RMS value; calculating a real power value based on the n instantaneous voltage values and the n instantaneous current values; calculating a power factor value based on the apparent power value and the real power value; and determining whether the power factor value is greater than a first threshold value to obtain a first determination result, and determining that a load is electrically coupled to the AC output terminal when the first determination result is yes.

In order to make the above objects, technical features and gains after actual implementation more obvious and easy to understand, in the following, the preferred embodiments will be described with reference to the corresponding drawings and will be described in more detail.

### BRIEF DESCRIPTION OF THE DRAWINGS

Other features and advantages of the present invention will become apparent in the following detailed description of the preferred embodiments with reference to the accompanying drawings, of which:

FIG. 1 shows an ideal voltage waveform 102 and an ideal current waveform 104 at an AC output terminal of a power device under no-load conditions.

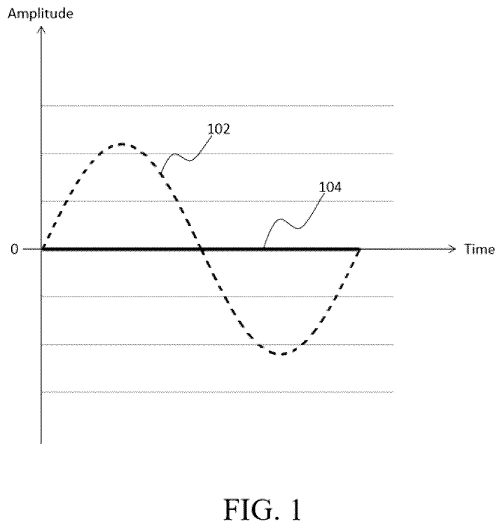

FIG. 2 shows a voltage waveform 202 and a current waveform 204 obtained by measuring the AC output terminal of the power device under no-load conditions.

FIG. 3 shows a voltage waveform 302 and a current waveform 304 obtained by measuring the AC output terminal of the power device under no-load conditions.

FIG. 4 shows a power device according to an embodiment of the present invention.

FIG. 5 is a flow chart of a method for determining whether a load is present according to an embodiment of the present invention.

FIG. 6 is a flow chart of a method for determining whether a load is present according to another embodiment of the present invention.

FIG. 7 is a schematic diagram showing the frequency components obtained when the power device 400 is under no-load conditions.

FIG. 8 is a schematic diagram showing the frequency components obtained when the power device 400 is under loaded conditions.

FIG. 9 is used to illustrate one execution sequence of the two processes shown in FIG. 5 and FIG. 6.

FIG. 10 shows the integration process corresponding to FIG. 9.

FIG. 11 is used to illustrate another execution sequence of the two processes shown in FIG. 5 and FIG. 6.

FIG. 12 shows the integration process corresponding to FIG. 11.

FIG. 13 shows a power device according to another embodiment of the present invention.

FIG. 14 shows a power device according to still another embodiment of the present invention.

FIG. 15 shows a power device according to still another embodiment of the present invention.

FIG. 16 shows a power device according to still another embodiment of the present invention.

FIG. 17 shows a power device according to still another embodiment of the present invention.

FIG. 18 shows a power device according to still another embodiment of the present invention.

FIG. 19 shows a power device according to still another embodiment of the present invention.

### DESCRIPTION OF EMBODIMENTS

The characteristics, contents, advantages and achieved effects of the present disclosure will become more fully understood from the detailed description given herein below and the accompanying drawings which are given by way of illustration only, and thus are not limitative of the present disclosure.

As required, detailed embodiments are disclosed herein. It must be understood that the disclosed embodiments are merely exemplary of and may be embodied in various and alternative forms, and combinations thereof. As used herein, the word “exemplary” is used expansively to refer to embodiments that serve as illustrations, specimens, models, or patterns. The figures are not necessarily to scale and some features may be exaggerated or minimized to show details of particular components. In other instances, well-known components, systems, materials, or methods that are known to those having ordinary skill in the art have not been described in detail in order to avoid obscuring the present disclosure. Therefore, specific structural and functional details disclosed herein are not to be interpreted as limiting, but merely as a basis for the claims and as a representative basis for teaching one skilled in the art.

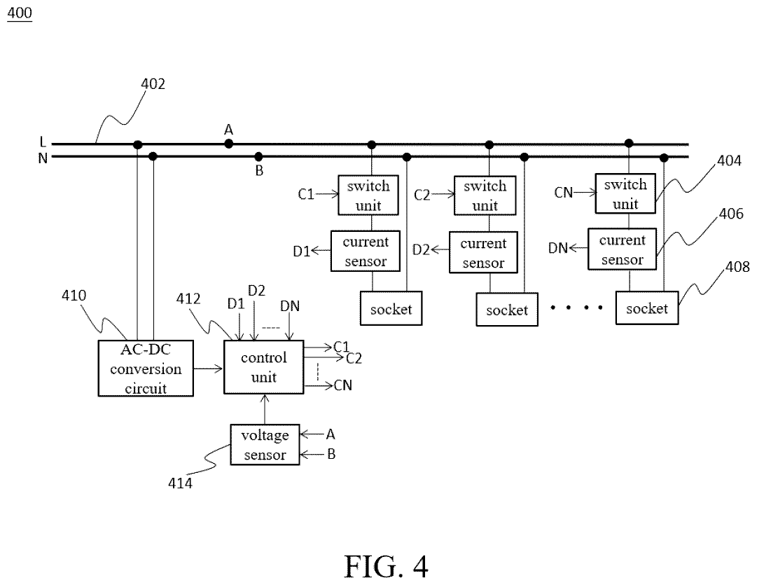

FIG. 4 shows a power device according to an embodiment of the present invention. From the circuit structure shown in FIG. 4, it can be seen that the power device 400 is a power distribution unit. The power device 400 comprises two conductors 402, a plurality of switch units 404, a plurality of current sensors 406, a plurality of sockets 408, an AC-DC conversion circuit 410, a control unit 412 and a voltage sensor 414. One of the conductors 402 is used to electrically couple with an AC input power source L, and the other conductor 402 is used to electrically couple with a neutral line N. Each of the aforementioned sockets 408 is used as an AC output terminal. In other words, the power device 400 has a plurality of AC output terminals, and each AC output terminal is implemented by a socket 408.

Each current sensor 406 is connected in series with one of the sockets 408 to obtain current sensing results D1-DN, respectively, where N is a natural number. Each switch unit 404 is electrically coupled to one of the two conductors 402, and is connected in series with one of the current sensors 406. In this embodiment, each switch unit 404 is electrically coupled between one of the two conductors 402 and one of the current sensors 406. Certainly, each switch unit 404 and its corresponding current sensor 406 may also be exchanged in position. The voltage sensor 414 is electrically coupled to the AC input power source L and the neutral line N through the two conductors 402 (which is equivalent to electrically coupling the voltage sensor to each AC output terminal) to obtain a voltage sensing result of the node A relative to the node B. The AC-DC conversion circuit 410 is electrically coupled to the two conductors 402, and is electrically coupled to the control unit 412 to provide operation power to the control unit 412. The control unit 412 is electrically coupled to the switch units 404, and uses control signals C1-CN to control the on/off states of the switch units 404. In addition, the control unit 412 is also electrically coupled to the voltage sensor 414 and the current sensors 406 to receive the aforementioned voltage sensing result and the current sensing results D1-DN.

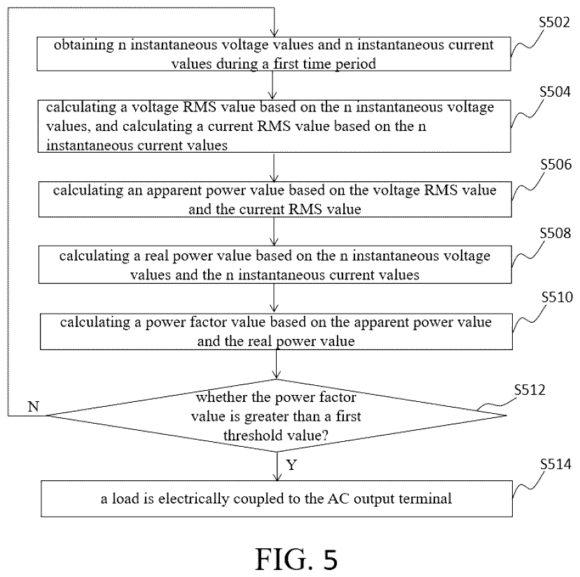

Next, it will be described how the power device 400 determines whether a load is present. FIG. 5 is a flow chart of a method for determining whether a load is present according to an embodiment of the present invention. Please refer to FIG. 5 and FIG. 4. Taking the socket 408 corresponding to the current sensing result D1 as an example, the control unit 412 can sample the voltage sensing result and the current sensing result D1 respectively based on a sampling frequency F1 to obtain n instantaneous voltage values and n instantaneous current values during a first time period (as shown in step S502), where n is a natural number. Taking the socket 408 corresponding to the current sensing result D2 as an example, the control unit 412 can obtain, through the voltage sensor 414 and the current sensor 406 corresponding to the current sensing result D2, n instantaneous voltage values and n instantaneous current values from the corresponding socket 408 during a first time period. In this embodiment, the duration of the first time period is, for example, 1 cycle (counted by the cycle of the AC voltage signal).

Next, the control unit 412 calculates a voltage RMS value based on the n instantaneous voltage values, and calculates a current RMS value based on the n instantaneous current values (as shown in step S504). In this embodiment, the control unit 412 calculates the voltage RMS value and the current RMS value based on the following equation (1) and equation (2), respectively:

$$V = \sqrt{\frac{{\sum }_{i = 1}^{n} {Vi}^{2}}{n}} \qquad ( 1 )$$

$$I = \sqrt{\frac{{\sum }_{i = 1}^{n} {Ii}^{2}}{n}} \qquad ( 2 )$$

Where Vi represents the i-th instantaneous voltage value, li represents the i-th instantaneous current value, and the value of i ranges from 1 to n.

Then, the control unit 412 calculates an apparent power value based on the voltage RMS value and the current RMS value (as shown in step S506). In this embodiment, the control unit 412 calculates the apparent power value based on the following equation (3):

$$S = V \times I \qquad ( 3 )$$

Next, the control unit 412 calculates a real power value based on the n instantaneous voltage values and the n instantaneous current values (as shown in step S508). In this embodiment, the control unit 412 calculates the real power value based on the following equation (4):

$$P = {\sum }_{i = 1}^{n} Vi \times Ii \qquad ( 4 )$$

Then, the control unit 412 calculates a power factor value based on the apparent power value and the real power value (as shown in step S510). In this embodiment, the control unit 412 calculates the power factor value based on the following equation (5):

$$cos θ = \frac{P}{S} \qquad ( 5 )$$

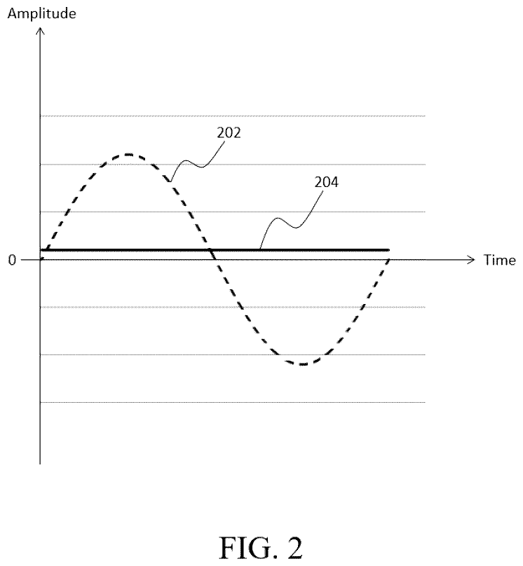

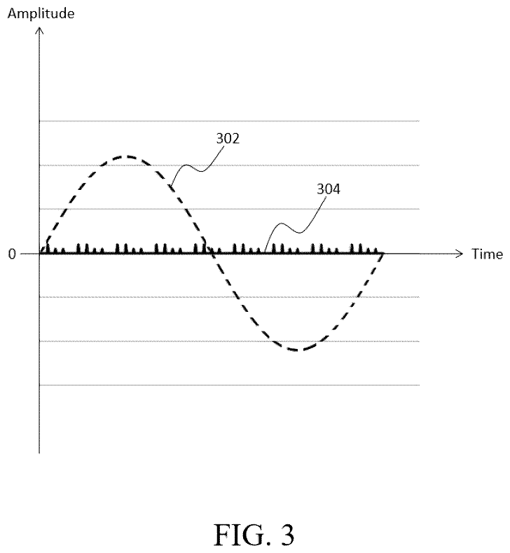

For the waveform shown in FIG. 2, since there is still noise at the drift level and the noise in the positive and negative half cycles is highly likely not symmetrical, the calculated real power value will be very close to 0 watts (W). Since the apparent power value calculated at this time is not 0 volt-ampere (VA), the calculated power factor value will be very close to 0. Similarly, for the waveform shown in FIG. 3, the calculated real power value will be very close to 0 watts (W), and the calculated apparent power value is not 0 volt-amperes (VA), so the calculated power factor value will be very close to 0.

Next, the control unit 412 determines whether the calculated power factor value is greater than a first threshold value (as shown in step S512) to obtain a first determination result. Since the power factor value may vary with the characteristics of the load and the usage scenario, the appropriate first threshold value may be selected based on experimental results. In this embodiment, the first threshold value is 0.2. When the first determination result is no, the control unit 412 returns to step S502; on the other hand, when the first determination result is yes, the control unit 412 determines that a load is electrically coupled to the corresponding socket 408 (i.e., the corresponding AC output terminal), as shown in step S514. That is, it determines that a load is present at the position of the corresponding socket 408.

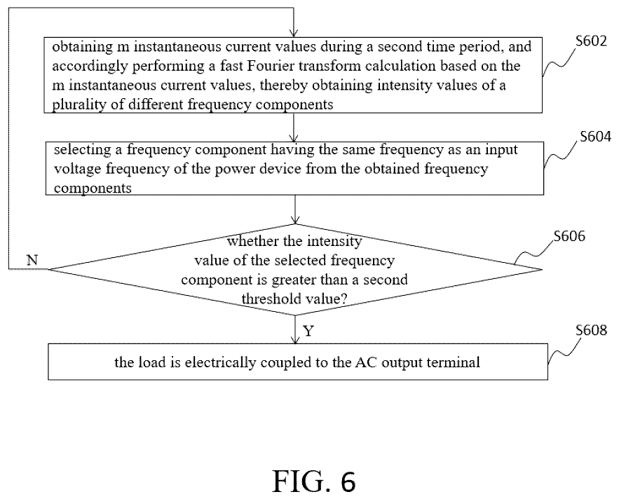

In order to avoid misjudgment, the control unit 412 can also execute a verification procedure, which is illustrated in FIG. 6. FIG. 6 is a flow chart of a method for determining whether a load is present according to another embodiment of the present invention. Please refer to FIG. 6 and FIG. 4. Taking the socket 408 corresponding to the current sensing result D1 as an example, the control unit 412 can sample the current sensing result D1 based on the aforementioned sampling frequency F1 to obtain m instantaneous current values during a second time period, and accordingly perform a fast Fourier transform (FFT) calculation based on the m instantaneous current values, thereby obtaining intensity values of a plurality of different frequency components (as shown in step S602). In this embodiment, m is a natural number and is greater than n, and the duration of the second time period is greater than the duration of the first time period. In this embodiment, the duration of the second time period is, for example, 8 cycles (counted by the cycles of the AC voltage signal).

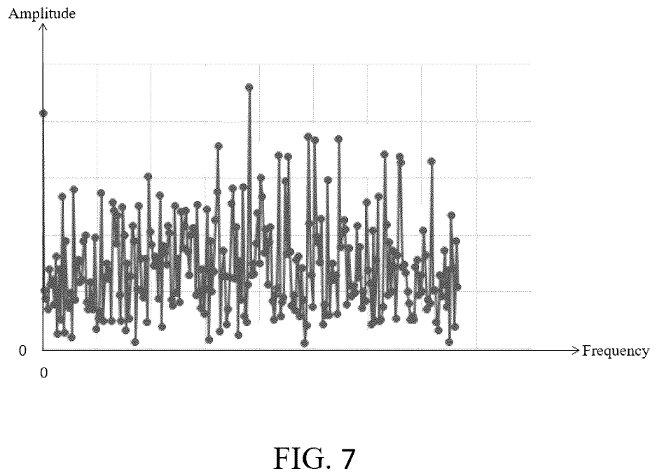

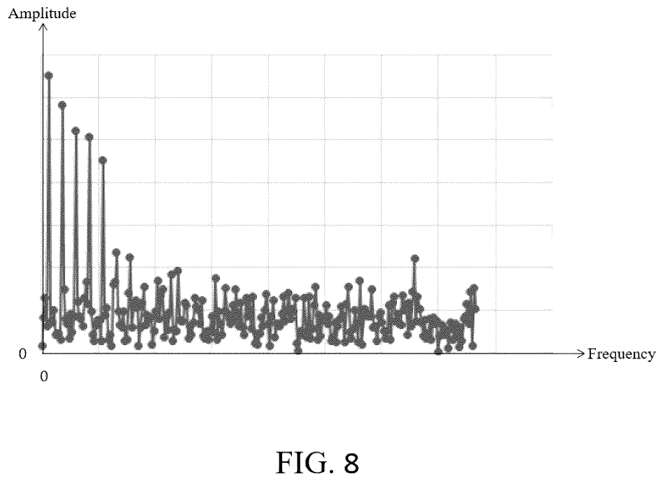

Next, the control unit 412 selects a frequency component having the same frequency as the input voltage frequency of the power device 400 from the obtained frequency components (as shown in step S604), which is explained with reference to FIG. 7 and FIG. 8. FIG. 7 is a schematic diagram showing the frequency components obtained when the power device 400 is under no-load conditions, and FIG. 8 is a schematic diagram showing the frequency components obtained when the power device 400 is under loaded conditions. By comparing FIG. 7 and FIG. 8, it can be seen that, under loaded conditions, there will be a large discrepancy in the amplitudes (i.e., intensity values) of the obtained frequency components. In addition, in FIG. 7 and FIG. 8, the frequency component with the largest amplitude is the frequency component that has the same frequency as the input voltage frequency (e.g., 60 Hz) of the power device 400.

Please continue to refer to FIG. 6 and FIG. 4. Next, the control unit 412 determines whether the intensity value of the selected frequency component is greater than a second threshold value (as shown in step S606) to obtain a second determination result. Certainly, the appropriate second threshold value may be selected based on experimental results. In this embodiment, the second threshold value is 300. When the second determination result is no, the control unit 412 returns to step S602; on the other hand, when the second determination result is yes, the control unit 412 determines that the load is electrically coupled to the corresponding socket 408 (i.e., the corresponding AC output terminal), as shown in step S608.

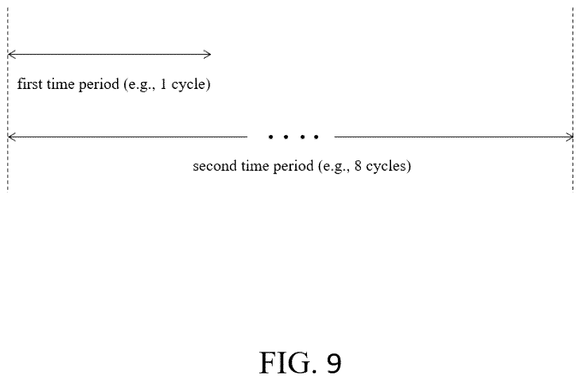

Since the execution of the fast Fourier transform calculation is relatively time-consuming, the power device 400 primarily executes the process shown in FIG. 5, while the process shown in FIG. 6 serves as a supplementary function. FIG. 9 is used to illustrate one execution sequence of the two processes shown in FIG. 5 and FIG. 6. As can be seen from FIG. 9, the first time period and the second time period start at the same time. Certainly, this is not intended to limit the present invention. Those of ordinary skill in the art should know that the first time period and the second time period do not necessarily have to start at the same time, as long as the first time period and the second time period at least partially overlap. In addition, in this embodiment, since the control unit 412 uses the sampling frequency F1 in both the first time period and the second time period, m is also k times n when the duration of the second time period is k times the duration of the first time period.

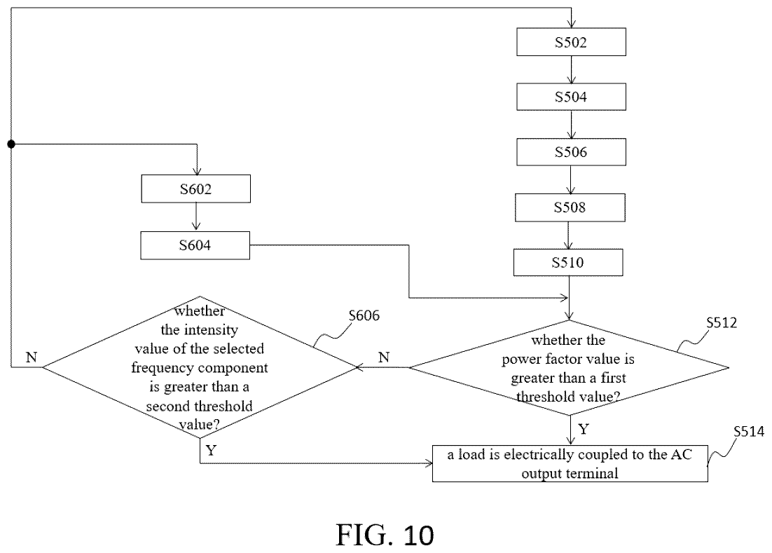

FIG. 10 shows the integration process corresponding to FIG. 9. In FIG. 10, the same symbols as those in FIG. 5 and FIG. 6 indicate the same operations. As shown in FIG. 10, when the control unit 412 determines that the calculated power factor value is greater than the first threshold value (as shown in step S512), the control unit 412 determines that a load is electrically coupled to the corresponding socket 408 (i.e., the corresponding AC output terminal), as shown in step S514. On the other hand, when the control unit 412 determines that the calculated power factor value is not greater than the first threshold value (as shown in step S512), the control unit 412 further determines whether the intensity value of the selected frequency component is greater than the second threshold value (as shown in step S606). When the determination result of step S606 is no, the control unit 412 returns to step S502 and step S602. On the other hand, when the determination result of step S606 is yes, the control unit 412 determines that a load is electrically coupled to the corresponding socket 408 (i.e., the corresponding AC output terminal), as shown in step S514.

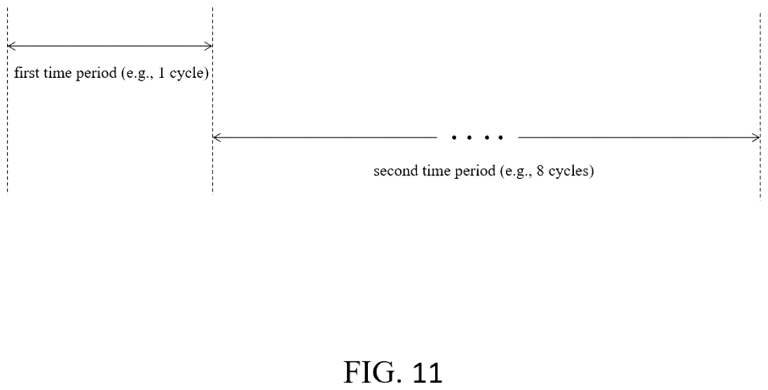

Certainly, when the computing time is not so critical, the control unit 412 may also adopt the timing shown in FIG. 11. FIG. 11 is used to illustrate another execution sequence of the two processes shown in FIG. 5 and FIG. 6. As can be seen from FIG. 11, the second time period is subsequent to the first time period. Certainly, this is not intended to limit the present invention. Those of ordinary skill in the art should know that the second time period may also be separated from the first time period by a predetermined time. In addition, in this embodiment, since the control unit 412 uses the sampling frequency F1 in both the first time period and the second time period, m is also k times n when the duration of the second time period is k times the duration of the first time period.

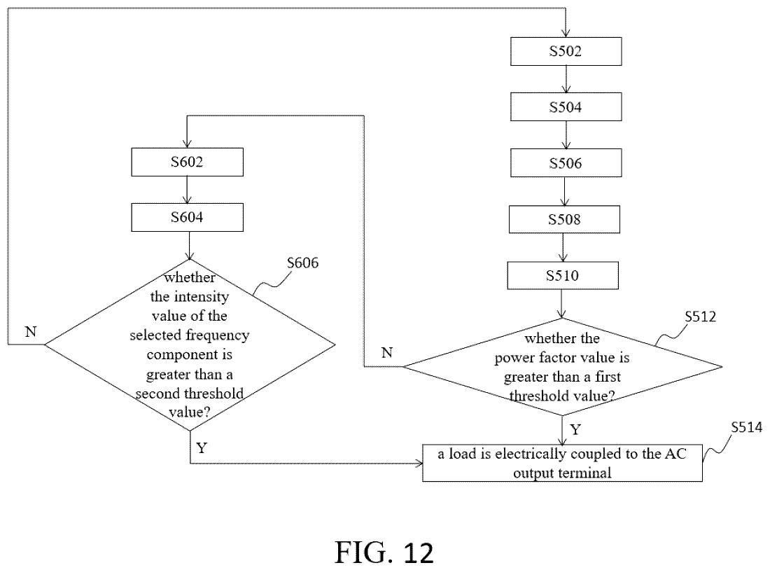

FIG. 12 shows the integration process corresponding to FIG. 11. In FIG. 12, the same symbols as those in FIG. 5 and FIG. 6 indicate the same operations. As shown in FIG. 12, when the control unit 412 determines that the calculated power factor value is greater than the first threshold value (as shown in step S512), the control unit 412 determines that a load is electrically coupled to the corresponding socket 408 (i.e., the corresponding AC output terminal), as shown in step S514. On the other hand, when the control unit 412 determines that the calculated power factor value is not greater than the first threshold value (as shown in step S512), the control unit 412 executes step S602. In addition, when the control unit 412 determines that the intensity value of the selected frequency component is greater than the second threshold value (as shown in step S606), the control unit 412 determines that a load is electrically coupled to the corresponding socket 408 (i.e., the corresponding AC output terminal), as shown in step S514. On the other hand, when the control unit 412 determines that the intensity value of the selected frequency component is not greater than the second threshold value (as shown in step S606), the control unit 412 returns to step S502.

It is worth mentioning that the first threshold value and the second threshold value mentioned above are only used for examples and are not used to limit the present invention. Those of ordinary skill in the art can select appropriate values based on actual needs. In addition, the control unit 412 may also use different sampling frequencies in the first time period and the second time period. For example, the control unit 412 may use the sampling frequency F1 during the first time period and use the sampling frequency F2 during the second time period. In addition, in other embodiments, the duration of the second time period may be less than or equal to the duration of the first time period. Certainly, the control unit 412 can execute the method for determining whether a load is present according to the present invention for each socket 408.

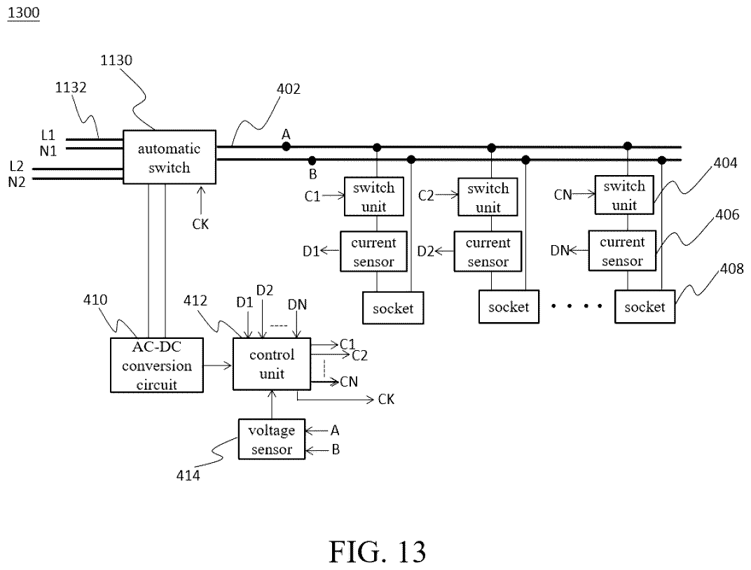

Based on the above teachings, a person skilled in the art should know that the method for determining whether a load is present according to the present invention can also be applied to other power devices, as illustrated in FIGS. 13 to 19.

FIG. 13 shows a power device according to another embodiment of the present invention. In FIG. 13, the same symbols as those in FIG. 4 indicate the same components or the same signals. From the circuit structure shown in FIG. 13, it can be seen that the power device 1300 is an automatic transfer switch. Compared to the power device 400 shown in FIG. 4, the power device 1300 shown in FIG. 13 further comprises an automatic switch 1130. The automatic switch 1130 is electrically coupled to an AC input power source L1, a neutral line N1, an AC input power source L2, and a neutral line N2 respectively through the four conductors 1132. The AC input power source L1 and the neutral line N1 are used to provide a first AC input power, and the AC input power source L2 and the neutral line N2 are used to provide a second AC input power.

The automatic switch 1130 is used to select one of the first AC input power and the second AC input power and transmit it to the AC-DC conversion circuit 410 and the two conductors 402 according to the control signal CK generated by the control unit 412, and to detect whether the transmitted AC input power has failed. When the automatic switch 1130 determines that the transmitted AC input power fails, it immediately switches to transmit another AC input power to the AC-DC conversion circuit 410 and the two conductors 402. In addition, the control unit 412 can execute the method for determining whether a load is present according to the present invention for each socket 408.

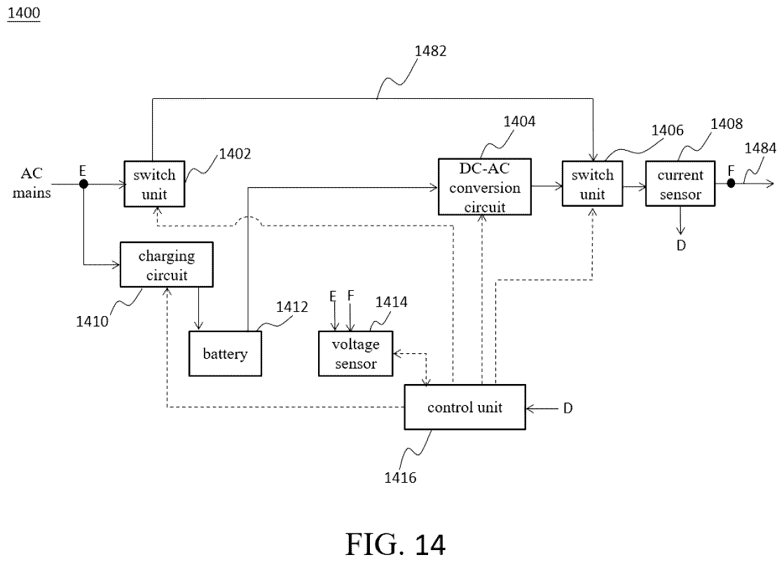

FIG. 14 shows a power device according to still another embodiment of the present invention. From the circuit structure shown in FIG. 14, it can be seen that the power device 1400 is an off-line uninterruptible power system (Off-line UPS). The power device 1400 comprises a switch unit 1402, a DC-AC conversion circuit 1404, a switch unit 1406, a current sensor 1408, a charging circuit 1410, a battery 1412, a voltage sensor 1414, a control unit 1416 and a bypass path 1482. In addition, the power device 1400 further comprises an AC output terminal 1484, and the current sensor 1408 is connected in series with the AC output terminal 1484. As for the voltage sensor 1414, it is electrically coupled to an AC input power source (e.g., the AC mains) and the AC output terminal 1484 to obtain a voltage sensing result of the connection point E and a voltage sensing result of the connection point F respectively.

The switch unit 1402 is electrically coupled to the AC input power source (e.g., the AC mains) and one terminal of the bypass path 1482. The switch unit 1406 is electrically coupled to the other terminal of the bypass path 1482, and is used to electrically couple to the AC output terminal 1484 through the current sensor 1408. The charging circuit 1410 is electrically coupled to the aforementioned AC input power source and the battery 1412. The DC-AC conversion circuit 1404 is electrically coupled between the battery 1412 and the switch unit 1406. In addition, the switch unit 1402, the switch unit 1406, the charging circuit 1410, the DC-AC conversion circuit 1404, the current sensor 1408, and the voltage sensor 1414 are electrically coupled to the control unit 1416 to be controlled by the control unit 1416. For example, the control unit 1416 may control the operation of the switch unit 1406 to determine whether to electrically couple the output terminal of the DC-AC conversion circuit 1404 to the current sensor 1408, or to electrically couple the bypass path 1482 to the current sensor 1408.

In addition, in this embodiment, the current sensor 1408 transmits the obtained current sensing result D to the control unit 1416, and the voltage sensor 1414 transmits the obtained voltage sensing results to the control unit 1416. The control unit 1416 can execute the method for determining whether a load is present according to the present invention for the AC output terminal 1484.

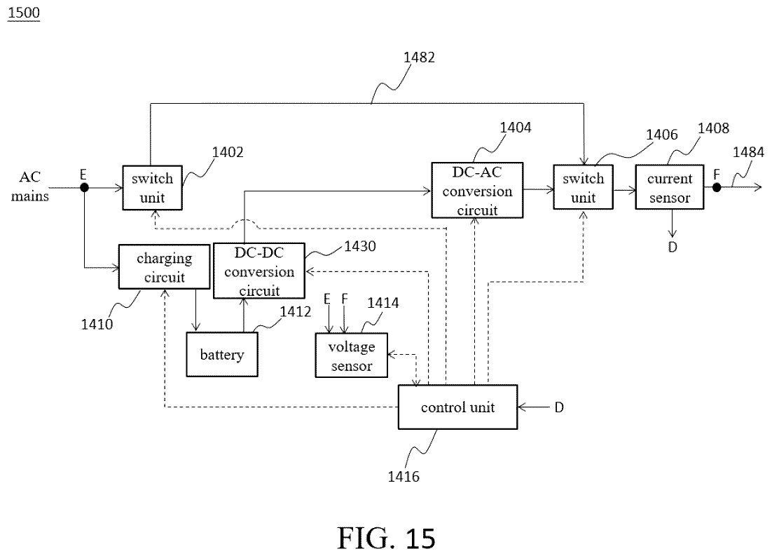

FIG. 15 shows a power device according to still another embodiment of the present invention. From the circuit structure shown in FIG. 15, it can be seen that the power device 1500 is an off-line uninterruptible power system. Compared to the off-line uninterruptible power system shown in FIG. 14, the off-line uninterruptible power system shown in FIG. 15 further comprises a DC-DC conversion circuit 1430. The DC-DC conversion circuit 1430 is electrically coupled between the battery 1412 and the input terminal of the DC-AC conversion circuit 1404, and is electrically coupled to the control unit 1416 to be controlled by the control unit 1416.

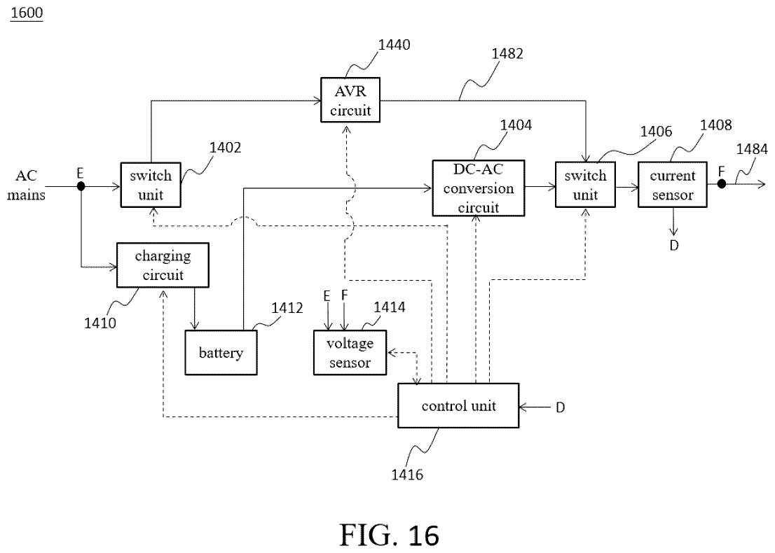

FIG. 16 shows a power device according to still another embodiment of the present invention. From the circuit structure shown in FIG. 16, it can be seen that the power device 1600 is a line-interactive uninterruptible power system (line-interactive UPS). Compared to the off-line uninterruptible power system shown in FIG. 14, the line-interactive uninterruptible power system shown in FIG. 16 further comprises an automatic voltage regulation circuit (AVR circuit) 1440. The automatic voltage regulation circuit 1440 is arranged on the bypass path 1482, and is electrically coupled to the control unit 1416 to be controlled by the control unit 1416.

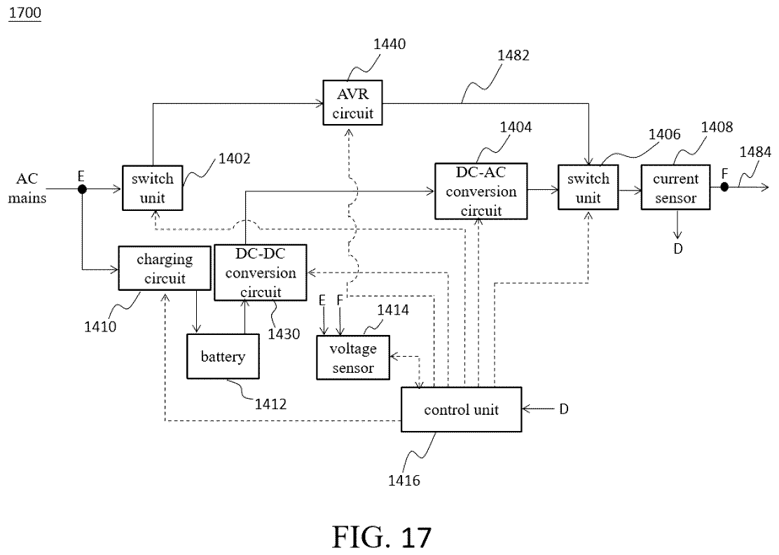

FIG. 17 shows a power device according to still another embodiment of the present invention. From the circuit structure shown in FIG. 17, it can be seen that the power device 1700 is a line-interactive uninterruptible power system. Compared to the line-interactive uninterruptible power system shown in FIG. 16, the line-interactive uninterruptible power system shown in FIG. 17 further comprises a DC-DC conversion circuit 1430. The DC-DC conversion circuit 1430 is electrically coupled between the battery 1412 and the input terminal of the DC-AC conversion circuit 1404, and is electrically coupled to the control unit 1416 to be controlled by the control unit 1416.

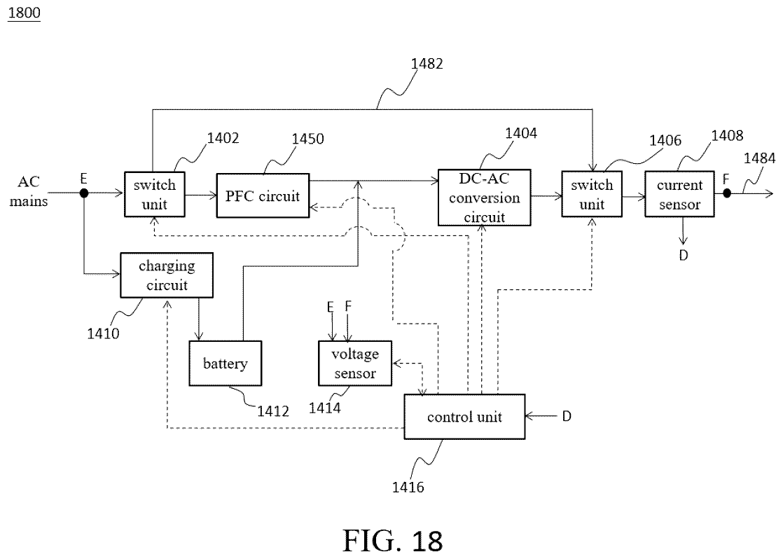

FIG. 18 shows a power device according to still another embodiment of the present invention. From the circuit structure shown in FIG. 18, it can be seen that the power device 1800 is an on-line uninterruptible power system (On-line UPS). Compared to the off-line uninterruptible power system shown in FIG. 14, the on-line uninterruptible power system shown in FIG. 18 further comprises a power factor correction circuit (PFC circuit) 1450. The power factor correction circuit 1450 is electrically coupled between the switch unit 1402 and the input terminal of the DC-AC conversion circuit 1404, and is electrically coupled to the control unit 1416 to be controlled by the control unit 1416. In addition, in this embodiment, the control unit 1416 can control the operation of the switch unit 1402 to determine whether to electrically couple the AC input power source to the bypass path 1482, or to electrically couple the AC input power source to the input terminal of the power factor correction circuit 1450.

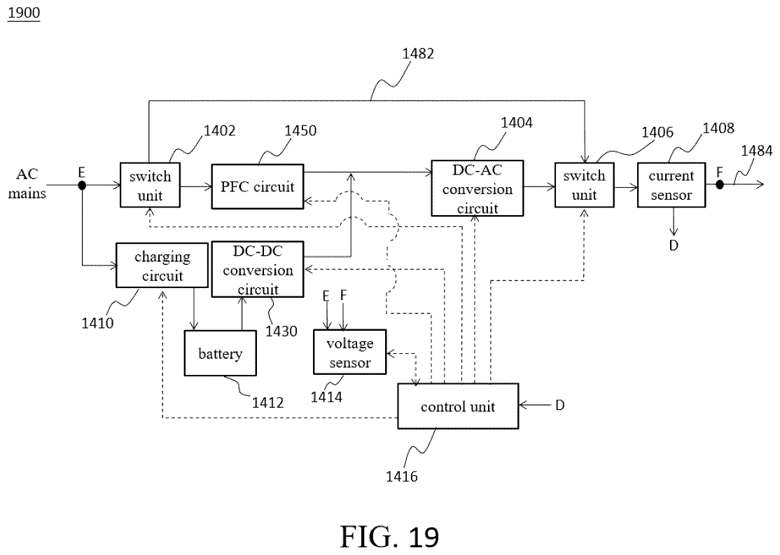

FIG. 19 shows a power device according to still another embodiment of the present invention. From the circuit structure shown in FIG. 19, it can be seen that the power device 1900 is an on-line uninterruptible power system. Compared to the on-line uninterruptible power system shown in FIG. 18, the on-line uninterruptible power system shown in FIG. 19 further comprises a DC-DC conversion circuit 1430. The DC-DC conversion circuit 1430 is electrically coupled between the battery 1412 and the input terminal of the DC-AC conversion circuit 1404, and is electrically coupled to the control unit 1416 to be controlled by the control unit 1416.

In summary, the power device of the present invention can accurately determine whether a load is present, and is not affected by level drift and noise.

The above-described embodiments are only for illustrating the technical ideas and characteristics of the present invention. Their purpose is to enable those of ordinary skill in the art to understand the content of the present invention and implement it accordingly. They cannot be used to limit the patent scope of the present invention. Any equivalent changes or modifications made in accordance with the spirit disclosed in the present invention should still be covered by the patent scope of the present invention.

What is claimed is:

1. A power device, comprising:
an AC output terminal;
a voltage sensor, electrically coupled to the AC output terminal;
a current sensor, connected in series with the AC output terminal; and
a control unit, electrically coupled to the voltage sensor and the current sensor, for obtaining, respectively through the voltage sensor and the current sensor, n instantaneous voltage values and n instantaneous current values from the AC output terminal during a first time period, wherein n is a natural number, the control unit being further used to calculate a voltage RMS value based on the n instantaneous voltage values, to calculate a current RMS value based on the n instantaneous current values, to calculate an apparent power value based on the voltage RMS value and the current RMS value, to calculate a real power value based on the n instantaneous voltage values and the n instantaneous current values, and to calculate a power factor value based on the apparent power value and the real power value, the control unit being further used to determine whether the power factor value is greater than a first threshold value to obtain a first determination result, and to determine that a load is electrically coupled to the AC output terminal when the first determination result is yes.

2. The power device as claimed in claim 1, wherein the control unit calculates the voltage RMS value and the current RMS value based on the following equation (1) and equation (2), respectively:
$$V = \sqrt{\frac{{\sum }_{i = 1}^{n} {Vi}^{2}}{n}} \qquad ( 1 )$$
$$I = \sqrt{\frac{{\sum }_{i = 1}^{n} {Ii}^{2}}{n}} \qquad ( 2 )$$
Where Vi represents the i-th instantaneous voltage value, Ii represents the i-th instantaneous current value, and the value of i ranges from 1 to n.

3. The power device as claimed in claim 2, wherein the control unit calculates the apparent power value based on the following equation (3):
$$S = V \times I . \qquad ( 3 )$$

4. The power device as claimed in claim 3, wherein the control unit calculates the real power value based on the following equation (4):
$$P = {\sum }_{i = 1}^{n} Vi \times Ii . \qquad ( 4 )$$

5. The power device as claimed in claim 4, wherein the control unit calculates the power factor value based on the following equation (5):
$$cos θ = \frac{P}{S} . \qquad ( 5 )$$

6. The power device as claimed in claim 1, wherein the first threshold value is 0.2.

7. The power device as claimed in claim 1, wherein the control unit further performs the following steps:
obtaining, through the current sensor, m instantaneous current values from the AC output terminal during a second time period, and accordingly performing a fast Fourier transform calculation based on the m instantaneous current values, thereby obtaining intensity values of a plurality of different frequency components;
selecting a frequency component having the same frequency as an input voltage frequency of the power device from the obtained frequency components;
determining whether the intensity value of the selected frequency component is greater than a second threshold value to obtain a second determination result; and
determining that the load is electrically coupled to the AC output terminal when the first determination result is no and the second determination result is yes.

8. The power device as claimed in claim 7, wherein the second threshold value is 300.

9. The power device as claimed in claim 7, wherein the first time period and the second time period at least partially overlap.

10. The power device as claimed in claim 7, wherein m is a natural number and is greater than n, and the duration of the second time period is greater than the duration of the first time period.

11. The power device as claimed in claim 1, wherein the power device is a power distribution unit, the AC output terminal is implemented by a socket, and the power device further comprises:
two conductors;
a switch unit, electrically coupled to one of the two conductors and connected in series with the current sensor; and
an AC-DC conversion circuit, electrically coupled to the two conductors,
wherein the switch unit and the AC-DC conversion circuit are electrically coupled to the control unit.

12. The power device as claimed in claim 1, wherein the power device is an automatic transfer switch, the AC output terminal is implemented by a socket, and the power device further comprises:
an automatic switch;
two conductors, one terminal of each conductor being electrically coupled to the automatic switch;
a switch unit, electrically coupled to one of the two conductors and connected in series with the current sensor; and
an AC-DC conversion circuit, electrically coupled to the automatic switch,
wherein the automatic switch, the switch unit and the AC-DC conversion circuit are electrically coupled to the control unit.

13. The power device as claimed in claim 1, wherein the power device is an uninterruptible power system, and further comprises:
a first switch unit, electrically coupled to an AC input power source and one terminal of a bypass path;
a second switch unit, electrically coupled to the other terminal of the bypass path, and electrically coupled to the AC output terminal through the current sensor;
a charging circuit, electrically coupled to the AC input power source and a battery; and
a DC-AC conversion circuit, electrically coupled between the battery and the second switch unit,
wherein the first switch unit, the second switch unit, the charging circuit and the DC-AC conversion circuit are electrically coupled to the control unit to be controlled by the control unit.

14. The power device as claimed in claim 13, further comprising a DC-DC conversion circuit electrically coupled between the battery and an input terminal of the DC-AC conversion circuit.

15. The power device as claimed in claim 13, further comprising an automatic voltage regulation circuit arranged on the bypass path.

16. The power device as claimed in claim 15, further comprising a DC-DC conversion circuit electrically coupled between the battery and an input terminal of the DC-AC conversion circuit.

17. The power device as claimed in claim 13, further comprising a power factor correction circuit electrically coupled between the first switch unit and an input terminal of the DC-AC conversion circuit.

18. The power device as claimed in claim 17, further comprising a DC-DC conversion circuit electrically coupled between the battery and an input terminal of the DC-AC conversion circuit.

19. A method for determining whether a load is present, applicable to a power device, the method comprising:
obtaining n instantaneous voltage values and n instantaneous current values from an AC output terminal of the power device during a first time period, wherein n is a natural number;
calculating a voltage RMS value based on the n instantaneous voltage values, and calculating a current RMS value based on the n instantaneous current values;
calculating an apparent power value based on the voltage RMS value and the current RMS value;
calculating a real power value based on the n instantaneous voltage values and the n instantaneous current values;
calculating a power factor value based on the apparent power value and the real power value; and
determining whether the power factor value is greater than a first threshold value to obtain a first determination result, and determining that a load is electrically coupled to the AC output terminal when the first determination result is yes.

20. The method as claimed in claim 19, wherein the voltage RMS value and the current RMS value are calculated based on the following equation (1) and equation (2), respectively:
$$V = \sqrt{\frac{{\sum }_{i = 1}^{n} {Vi}^{2}}{n}} \qquad ( 1 )$$
$$I = \sqrt{\frac{{\sum }_{i = 1}^{n} {Ii}^{2}}{n}} \qquad ( 2 )$$
Where Vi represents the i-th instantaneous voltage value, li represents the i-th instantaneous current value, and the value of i ranges from 1 to n.

21. The method as claimed in claim 20, wherein the apparent power value is calculated based on the following equation (3):
$$S = V \times I . \qquad ( 3 )$$

22. The method as claimed in claim 21, wherein the real power value is calculated based on the following equation (4):
$$P = {\sum }_{i = 1}^{n} Vi \times Ii . \qquad ( 4 )$$

23. The method as claimed in claim 22, wherein the power factor value is calculated based on the following equation (5):
$$cos θ = \frac{P}{S} . \qquad ( 5 )$$

24. The method as claimed in claim 17, wherein the first threshold value is 0.2.

25. The method as claimed in claim 17, further comprising:
obtaining m instantaneous current values from the AC output terminal during a second time period, and accordingly performing a fast Fourier transform calculation based on the m instantaneous current values, thereby obtaining intensity values of a plurality of different frequency components;
selecting a frequency component having the same frequency as an input voltage frequency of the power device from the obtained frequency components;
determining whether the intensity value of the selected frequency component is greater than a second threshold value to obtain a second determination result; and
determining that the load is electrically coupled to the AC output terminal when the first determination result is no and the second determination result is yes.

26. The method as claimed in claim 25, wherein the second threshold value is 300.

27. The method as claimed in claim 25, wherein the first time period and the second time period at least partially overlap.

28. The method as claimed in claim 25, wherein m is a natural number and is greater than n, and the duration of the second time period is greater than the duration of the first time period.
